(19) United States
(12) Patent Application Publication
(10) Pub. No.: US 2025/0331373 A1
(43) Pub. Date: Oct. 23, 2025

(54) DISPLAY PANEL AND DISPLAY DEVICE

(71) Applicant: Wuhan Tianma Microelectronics Co., Ltd., Wuhan (CN)

(72) Inventor: Wanqiu Zhang, Wuhan (CN)

(73) Assignee: Wuhan Tianma Microelectronics Co., Ltd., Wuhan (CN)

(21) Appl. No.: 19/252,364

(22) Filed: Jun. 27, 2025

(30) Foreign Application Priority Data
Apr. 8, 2025 (CN) 202510435827.3

(51) Int. Cl. H10K 59/126; G09G 3/3233; H10K 59/121; H10K 59/131

(52) U.S. Cl. CPC H10K 59/126; G09G 3/3233; H10K 59/1213; H10K 59/131; G09G 2300/0819; G09G 2310/08; G09G 2320/028; G09G 2330/021

(57) ABSTRACT

A display panel and a display device. The display panel includes a substrate, a display light-emitting device, an anti-peeping light-emitting device, a shielding layer, a display pixel circuit and an anti-peeping pixel circuit. In a direction perpendicular to a plane of the substrate, the shielding layer completely covers the anti-peeping light-emitting device and does not overlap with the display light-emitting device. The display pixel circuit is electrically connected to the display light-emitting device, and the anti-peeping pixel circuit is electrically connected to the anti-peeping light-emitting device. In a normal display mode, the display light-emitting device emits light and the anti-peeping light-emitting device does not emit light. In an anti-peeping display mode, both the display light-emitting device and the anti-peeping light-emitting device emit light. Both the anti-peeping pixel circuit and the display pixel circuit are electrically connected to a same voltage signal line, and/or to a same scan signal line.

### CROSS-REFERENCE TO RELATED APPLICATIONS

The present application claims priority to Chinese Patent Application No. 202510435827.3 filed on Apr. 8, 2025, the content of which is incorporated herein by reference in its entirety.

### TECHNICAL FIELD

The present disclosure relates to the field of display technologies, and in particular, to a display panel and a display device.

### BACKGROUND

Currently, display devices have become indispensable in modern works and daily life. However, in public places, surrounding people may inadvertently or intentionally view the display content displayed on someone's display device, which potentially results in a leakage of sensitive information.

Therefore, there is a growing demand for an anti-peeping function of a display device, which brings an urgent need for a technical solution therefor.

### SUMMARY

In view of this, embodiments of the present disclosure provide a display panel and a display device, aiming to solve the above-mentioned problems.

In an aspect, an embodiment of the present disclosure provides a display panel, including a substrate, light-emitting devices, a shielding layer, a display pixel circuit, and an anti-peeping pixel circuit. The light-emitting devices are located at a side of the substrate and include a display light-emitting device and an anti-peeping light-emitting device. The shielding layer is located at a side of the anti-peeping light-emitting device away from the substrate. Along a direction perpendicular to a plane of the substrate, the shielding layer completely covers the anti-peeping light-emitting device and does not overlap with the display light-emitting device. The display pixel circuit and the anti-peeping pixel circuit are located between the substrate and the light-emitting devices. The display pixel circuit is electrically connected to the display light-emitting device, and the anti-peeping pixel circuit is electrically connected to the anti-peeping light-emitting device. Display modes of the display panel include a normal display mode and an anti-peeping display mode. In the normal display mode, the display light-emitting device emits light, and the anti-peeping light-emitting device does not emit light. In the anti-peeping display mode, both the display light-emitting device and the anti-peeping light-emitting device emit light. Both the anti-peeping pixel circuit and the display pixel circuit are electrically connected to a same voltage signal line, and/or both the anti-peeping pixel circuit and the display pixel circuit are electrically connected to a same scan signal line.

In another aspect, based on the same inventive concept, an embodiment of the present disclosure provides a display device, including a display pane including: a substrate, light-emitting devices, a shielding layer, a display pixel circuit, and an anti-peeping pixel circuit. The light-emitting devices are located at a side of the substrate and include a display light-emitting device and an anti-peeping light-emitting device. The shielding layer is located at a side of the anti-peeping light-emitting device away from the substrate. Along a direction perpendicular to a plane of the substrate, the shielding layer completely covers the anti-peeping light-emitting device and does not overlap with the display light-emitting device. The display pixel circuit and the anti-peeping pixel circuit are located between the substrate and the light-emitting devices. The display pixel circuit is electrically connected to the display light-emitting device, and the anti-peeping pixel circuit is electrically connected to the anti-peeping light-emitting device. Display modes of the display panel include a normal display mode and an anti-peeping display mode. In the normal display mode, the display light-emitting device emits light, and the anti-peeping light-emitting device does not emit light. In the anti-peeping display mode, both the display light-emitting device and the anti-peeping light-emitting device emit light. Both the anti-peeping pixel circuit and the display pixel circuit are electrically connected to a same voltage signal line, and/or both the anti-peeping pixel circuit and the display pixel circuit are electrically connected to a same scan signal line.

### BRIEF DESCRIPTION OF DRAWINGS

In order to better describe the technical solutions of embodiments of the present disclosure, the following briefly describes the drawings desired in the embodiments. It is appreciated that, the drawings described below are merely some embodiments of the present disclosure, and for those skilled in the art, other drawings can be obtained based on these drawings without creative effort.

FIG. 1 is a schematic structural diagram of a display panel according to an embodiment of the present disclosure;

FIG. 2 is a schematic diagram of a display pixel circuit according to an embodiment of the present disclosure;

FIG. 3 is a schematic diagram of the display pixel circuit shown in FIG. 2;

FIG. 4 is another schematic diagram of the display pixel circuit shown in FIG. 2;

FIG. 5 is a schematic diagram of connection between a display pixel circuit and an anti-peeping pixel circuit according to an embodiment of the present disclosure;

FIG. 6 is a schematic diagram of connection between another display pixel circuit and an anti-peeping pixel circuit according to an embodiment of the present disclosure;

FIG. 7 is a schematic diagram of an anti-peeping pixel circuit according to an embodiment of the present disclosure;

FIG. 8 is a schematic waveform diagram of a reset voltage signal line according to an embodiment of the present disclosure;

FIG. 9 is a schematic diagram of connection between another anti-peeping pixel circuit and a display pixel circuit according to an embodiment of the present disclosure;

FIG. 10 is a schematic diagram of the anti-peeping pixel circuit and the display pixel circuit shown in FIG. 9;

FIG. 11 is a timing diagram of the anti-peeping pixel circuit and the display pixel circuit shown in FIG. 10;

FIG. 12 is another schematic diagram of the anti-peeping pixel circuit and the display pixel circuit shown in FIG. 9;

FIG. 13 is a schematic waveform diagram of a bias voltage signal line according to an embodiment of the present disclosure;

FIG. 14 is another schematic diagram of connection between an anti-peeping pixel circuit and a display pixel circuit according to an embodiment of the present disclosure;

FIG. 15 is a schematic waveform diagram of a first voltage signal line according to an embodiment of the present disclosure;

FIG. 16 is a partial plan diagram of a display panel according to an embodiment of the present disclosure;

FIG. 17 is a structural diagram of another display panel according to an embodiment of the present disclosure;

FIG. 18 is a partial plan diagram of another display panel according to an embodiment of the present disclosure;

FIG. 19 is a schematic structural diagram of another display panel according to an embodiment of the present disclosure;

FIG. 20 is a schematic structural diagram of another display panel according to an embodiment of the present disclosure; and

FIG. 21 is a schematic diagram of a display device according to an embodiment of the present disclosure.

### DESCRIPTION OF EMBODIMENTS

In order to better illustrate the technical solutions of the present disclosure, embodiments of the present disclosure are described in detail as follows with reference to the drawings.

It should be noted that, the described embodiments are merely some of, rather than all of the embodiments of the present disclosure. All other embodiments obtained by those skilled in the art without creative efforts according to the embodiments of the present disclosure shall fall within a scope of the present disclosure.

The terms used in the embodiments of the present disclosure are only for the purpose of describing specific embodiments, and are not intended to limit the present disclosure. The singular forms “a/an”, “said”, and “the” used in the embodiments of the present disclosure and the attached claims are also intended to include plural forms thereof, unless noted otherwise.

It should be understood that the term “and/or” used herein is merely an association relationship describing associated objects, indicating that there may be three relationships, for example, A and/or B may indicate three cases, i.e., A existing individually, A and B existing simultaneously, B existing individually. In addition, the symbol “/” in the context generally indicates that the relation between the objects in front and at the back of “/” is an “or” relationship.

Various modifications and changes can be made to the present disclosure without departing from the scope of the disclosure, which are obvious to those skilled in the art. Accordingly, the present disclosure is intended to cover the modifications and variations of the present disclosure that fall within the scope of corresponding claims (claimed technical solutions) and their equivalents. It should be noted that the embodiments of the present disclosure can be combined mutually in the case of no conflict.

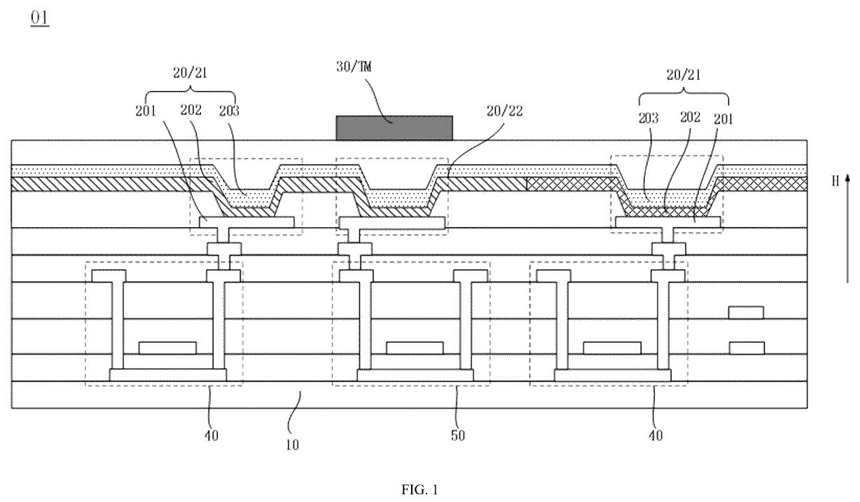

FIG. 1 is a schematic structural diagram of a display panel according to an embodiment of the present disclosure.

An embodiment of the present disclosure provides a display panel 01, as shown in FIG. 1, the display panel 01 includes a substrate 10, light-emitting devices 20, a shielding layer 30, a display pixel circuit 40, and an anti-peeping pixel circuit 50. The light-emitting devices 20 are located at a side of the substrate 10, and include a display light-emitting device 21 and an anti-peeping light-emitting device 22. The display light-emitting device 21 is configured to display an image, and the anti-peeping light-emitting device 22 is configured to perform anti-peeping display.

In an embodiment, the light-emitting device 20 is one of an organic light-emitting diode (OLED), a micro light-emitting diode (micro-LED), and a mini-light-emitting diode (mini-LED). FIG. 1 only illustrates a case that the light-emitting device 20 is an OLED.

In an embodiment, as shown in FIG. 1, the display light-emitting device 21 and the anti-peeping light-emitting device 22 are provided in a same layer.

The shielding layer 30 is located at a side of the anti-peeping light-emitting device 22 away from the substrate 10. Along a direction H perpendicular to a plane of the substrate 10, the shielding layer 30 completely covers the anti-peeping light-emitting device 22, and the shielding layer 30 does not overlap with the display light-emitting device 21. In this way, the shielding layer 30 can be configured to shield light emission from a front surface of the anti-peeping light-emitting device 22, without affecting light emission from a front surface of the display light-emitting device 21.

The display pixel circuit 40 and the anti-peeping pixel circuit 50 are located between the substrate 10 and the light-emitting devices 20. The display pixel circuit 40 is electrically connected to the display light-emitting device 21 and is configured to drive the display light-emitting device 21 to emit light. The display pixel circuit 40 may include multiple transistors, and FIG. 1 only illustrates one transistor in the display pixel circuit 40.

The anti-peeping pixel circuit 50 is electrically connected to the anti-peeping light-emitting device 22 and is configured to drive the anti-peeping light-emitting device 22 to emit light. The anti-peeping pixel circuit 50 may include at least one transistor, and FIG. 1 only illustrates one transistor in the anti-peeping pixel circuit 50.

Display modes of the display panel 01 include a normal display mode and an anti-peeping display mode. In the normal display mode, the display light-emitting device 21 emits light, and the anti-peeping light-emitting device 22 does not emit light. In the anti-peeping display mode, the display light-emitting device 21 emits light and the anti-peeping light-emitting device 22 emits light.

Both the anti-peeping pixel circuit 50 and the display pixel circuit 40 are electrically connected to a same voltage signal line, and/or the anti-peeping pixel circuit 50 and the display pixel circuit 40 are electrically connected to a same scan signal line.

That is, the anti-peeping pixel circuit 50 and the display pixel circuit 40 may share a same voltage signal line, or share a same scan signal line, or may share both the same voltage signal line and the same scan signal line.

In embodiments of the present disclosure, in the normal display mode of the display panel 01, the display light-emitting device 21 emits light, while the anti-peeping light-emitting device 22 does not emit light, so that the light emitted from the display light-emitting device 21 is not interfered by the anti-peeping light-emitting device 22, thereby realizing normal display of the display light-emitting device 21. In the anti-peeping display mode of the display panel 01, both the display light-emitting device 21 and the anti-peeping light-emitting device 22 emit light, so that a small viewing angle light emitted by the anti-peeping light-emitting device 22 can be shielded by the shielding layer 30, and a large viewing angle light emitted by the anti-peeping light-emitting device 22 can interfere with a large viewing angle display of the display light-emitting device 21, thereby realizing large viewing angle anti-peeping without affecting the front display of the display panel 01, preventing the display content of the display panel 01 from being peeped by the surrounding individuals, and thus meeting users' demands for active anti-peeping of the display panel 01.

Moreover, the arrangement of the anti-peeping pixel circuit 50 and the display pixel circuit 40 share a same voltage signal line and/or a same scan signal line is also beneficial to reducing the structural complexity of the peripheral circuit driving the anti-peeping pixel circuit 50 and the display pixel circuit 40, and thus simplifying the structure of the display panel 01.

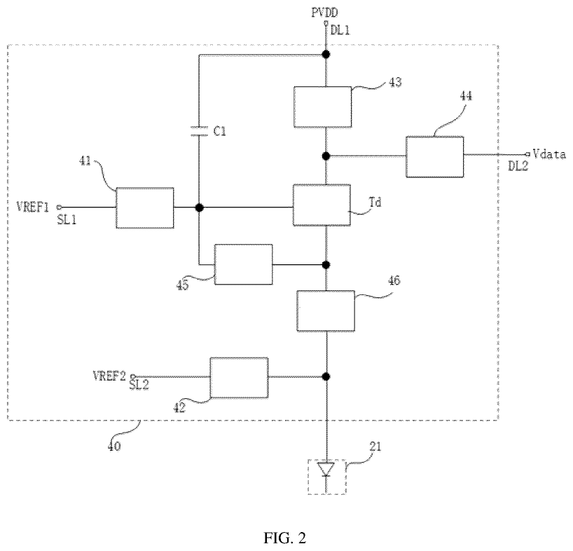

In an embodiment, as shown in FIG. 2, which is a schematic diagram of a display pixel circuit according to an embodiment of the present disclosure, the display pixel circuit 40 includes a driving transistor Td, a first reset circuit 41 and a second reset circuit 42. An input terminal of the first reset circuit 41 is electrically connected to a first reset voltage signal line SL1, an output terminal of the first reset circuit 41 is electrically connected to a gate of the driving transistor Td. The first reset voltage signal line SL1 is configured to transmit a first reset voltage VREF1 to the first reset circuit 41. The first reset circuit 41 is configured to transmit the first reset voltage VREF1 to the gate of the driving transistor Td to reset the gate of the driving transistor Td.

An input terminal of the second reset circuit 42 is electrically connected to a second reset voltage signal line SL2. An output terminal of the second reset circuit 42 is electrically connected to a first electrode of the display light-emitting device 21. The second reset voltage signal line SL2 is configured to transmit a second reset voltage VREF2 to the second reset circuit 42. The second reset circuit 42 is configured to transmit the second reset voltage VREF2 to the first electrode of the display light-emitting device 21 to reset the first electrode of the display light-emitting device 21. The first electrode of the display light-emitting device 21 may be an anode thereof.

It may be understood that the first reset voltage VREF1 and the second reset voltage VREF2 may be the same or different from each other, and may be specifically set according to actual needs.

In addition, as shown in FIG. 2, the display pixel circuit 40 further includes a power supply voltage writing circuit 43, a data writing circuit 44, a threshold capturing circuit 45, a light-emitting control circuit 46 and a first storage capacitor C1. An input terminal of the power supply voltage writing circuit 43 is electrically connected to the power supply voltage signal line DL1, an output terminal of the power supply voltage writing circuit 43 is electrically connected to a first electrode of the driving transistor Td. The power supply voltage signal line DL1 is configured to transmit the power supply voltage PVDD to the power supply voltage writing circuit. An input terminal of the data writing circuit 44 is electrically connected to the data signal line DL2, an output terminal of the data writing circuit 44 is electrically connected to the first electrode of the driving transistor Td. The data signal line DL2 is configured to transmit a data voltage Vdata to the data writing circuit 44.

An input terminal of the threshold capturing circuit 45 is electrically connected to a second electrode of the driving transistor Td, an output terminal of the threshold capturing circuit 45 is electrically connected to the gate of the driving transistor Td. An input terminal of the light-emitting control circuit 46 is electrically connected to the second electrode of the driving transistor Td, and an output terminal of the light-emitting control circuit 46 is electrically connected to the first electrode of the display light-emitting device 21. An electrode plate of the first storage capacitor C1 is electrically connected to the gate of the driving transistor Td, and another electrode plate of the first storage capacitor C1 is electrically connected to the power supply voltage signal line DL1.

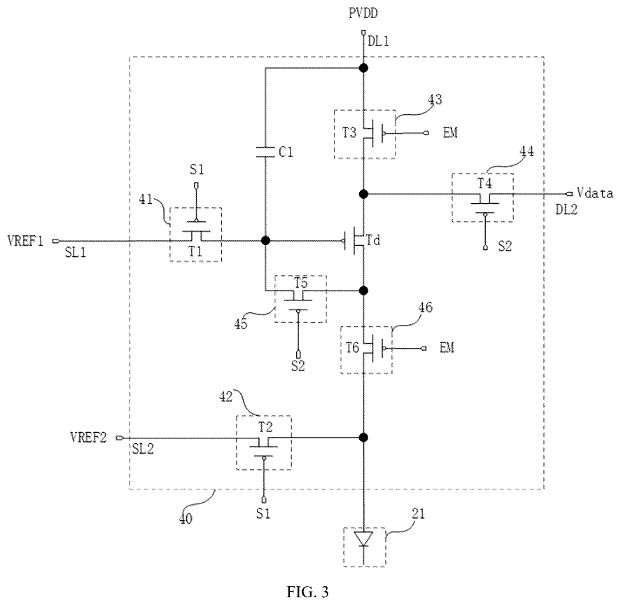

Exemplarily, as shown in FIG. 3, which is a schematic diagram of the display pixel circuit shown in FIG. 2, the first reset circuit 41 includes a first transistor T1. A first electrode of the first transistor T1 is electrically connected to the first reset voltage signal line SL1, a second electrode of the first transistor T1 is electrically connected to the gate of the driving transistor Td, and a gate of the first transistor T1 is electrically connected to the first scan signal line S1. The second reset circuit 42 includes a second transistor T2. A first electrode of the second transistor T2 is electrically connected to the second reset voltage signal line SL2, a second electrode of the second transistor T2 is electrically connected to the first electrode of the display light-emitting device 21, and a gate of the second transistor T2 is electrically connected to the first scan signal line S1.

The power supply voltage writing circuit 43 includes a third transistor T3. A first electrode of the third transistor T3 is electrically connected to the power supply voltage signal line DL1, a second electrode of the third transistor T3 is electrically connected to the first electrode of the driving transistor Td, and a gate of the third transistor T3 is electrically connected to a light-emitting control signal line EM. The data writing circuit 44 includes a fourth transistor T4. A first electrode of the fourth transistor T4 is electrically connected to the data signal line DL2, a second electrode of the fourth transistor T4 is electrically connected to the first electrode of the driving transistor Td, and a gate of the fourth transistor T4 is electrically connected to the second scan signal line S2.

The threshold capturing circuit 45 includes a fifth transistor T5. A first electrode of the fifth transistor T5 is electrically connected to the second electrode of the driving transistor Td, a second electrode of the fifth transistor T5 is electrically connected to the gate of the driving transistor Td, and a gate of the fifth transistor T5 is electrically connected to the second scan signal line S2. The light-emitting control circuit 46 includes a sixth transistor T6. A first electrode of the sixth transistor T6 is electrically connected to the second electrode of the driving transistor Td, a second electrode of the sixth transistor T6 is electrically connected to the first electrode of the display light-emitting device 21, and a gate of the sixth transistor T6 is electrically connected to the light-emitting control signal line EM.

Exemplarily, as shown in FIG. 3, the driving transistor Td, the first transistor T1, the second transistor T2, the third transistor T3, the fourth transistor T4, the fifth transistor T5 and the sixth transistor T6 are all P-type transistors (that is, a low level is an enable signal, and a high level is a disable signal).

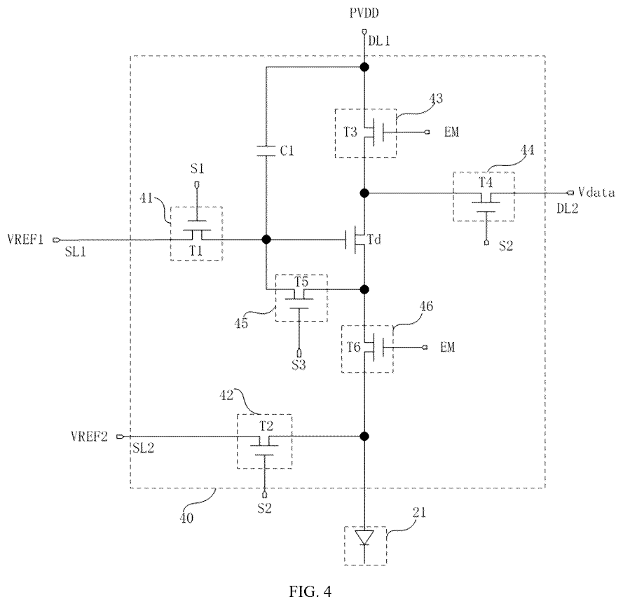

Exemplarily, as shown in FIG. 4, which is another schematic diagram of the display pixel circuit shown in FIG. 2, a difference between the display pixel circuit shown in FIG. 4 and the display pixel circuit shown in FIG. 3 may be as follows: the driving transistor Td, the first transistor T1, the second transistor T2, the third transistor T3, the fourth transistor T4, the fifth transistor T5 and the sixth transistor T6 are all N-type transistors (that is, a high level is an enable signal, and a low level is a disable signal), a gate of the second transistor T2 is electrically connected to the second scan signal line S2, and a gate of the fifth transistor T5 is electrically connected to the third scan signal line S3. It should be noted that the third scan signal line S3 connected to a previous display pixel circuit 40 may be electrically connected to the first scan signal line S1 connected to a next display pixel circuit 40.

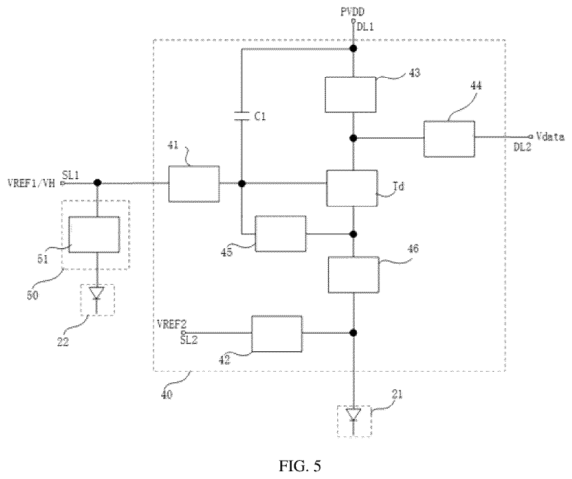

FIG. 5 is a schematic diagram of connection between a display pixel circuit and an anti-peeping pixel circuit according to an embodiment of the present disclosure.

In an embodiment of the present disclosure, as shown in FIG. 5, the anti-peeping pixel circuit 50 includes an anti-peeping driving circuit 51. An input terminal of the anti-peeping driving circuit 51 is electrically connected to the first reset voltage signal line SL1, an output terminal of the anti-peeping driving circuit 51 is electrically connected to the first electrode of the anti-peeping light-emitting device 22. The first reset voltage signal line SL1 is further configured to transmit an anti-peeping driving voltage VH to the anti-peeping driving circuit 51. The anti-peeping driving circuit 51 transmits the anti-peeping driving voltage VH to the anti-peeping light-emitting device 22, so as to drive the anti-peeping light-emitting device 22 to emit light.

In the anti-peeping display mode, activation periods of the first reset circuit 41 and the anti-peeping driving circuit 51 are at least partially different from each other, and the first reset voltage signal line SL1 transmits the first reset voltage VREF1 and the anti-peeping driving voltage VH in a time-division manner.

Based on this arrangement, in an embodiment of the present disclosure, the anti-peeping pixel circuit 50 and the display pixel circuit 40 may share a same first reset voltage signal line SL1. In the anti-peeping display mode, the first reset voltage signal line SL1 may transmit the anti-peeping driving voltage VH in the activation period of the anti-peeping driving circuit 51, so as to drive the anti-peeping light-emitting device 22 to emit light. The first reset voltage VREF1 is transmitted in an activation period of the first reset circuit 41, so as to reset the gate of the driving transistor Td in the display pixel circuit 50.

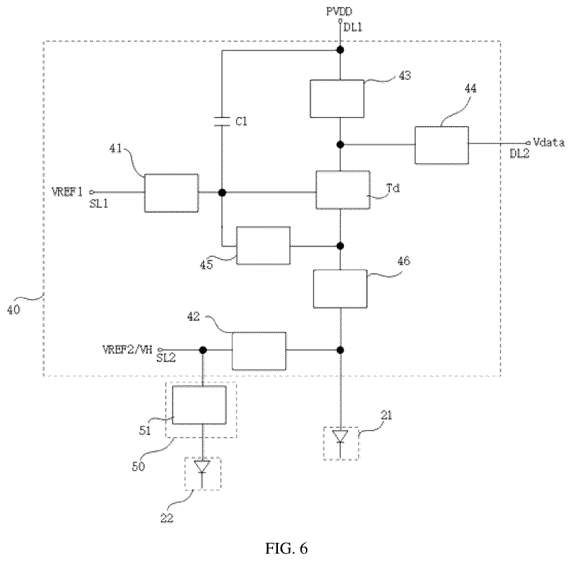

FIG. 6 is a schematic diagram of connection between another display pixel circuit and an anti-peeping pixel circuit according to an embodiment of the present disclosure.

In an embodiment of the present disclosure, as shown in FIG. 6, the anti-peeping pixel circuit 50 includes an anti-peeping driving circuit 51. An input terminal of the anti-peeping driving circuit 51 is electrically connected to the second reset voltage signal line SL2, an output terminal of the anti-peeping driving circuit 51 is electrically connected to the first electrode of the anti-peeping light-emitting device 22. The second reset voltage signal line SL2 is further configured to transmit an anti-peeping driving voltage VH to the anti-peeping driving circuit 51. The anti-peeping driving circuit 51 transmits the anti-peeping driving voltage VH to the anti-peeping light-emitting device 22, so as to drive the anti-peeping light-emitting device 22 to emit light.

In the anti-peeping display mode, activation periods of the second reset circuit 42 and the anti-peeping driving circuit 51 are at least partially different from each other, and the second reset voltage signal line SL2 transmits the second reset voltage VREF2 and the anti-peeping driving voltage VH in a time-division manner.

Based on this arrangement, in an embodiment of the present disclosure, the anti-peeping pixel circuit 50 and the display pixel circuit 40 may share a same second reset voltage signal line SL2. In the anti-peeping display mode, the second reset voltage signal line SL2 may transmit the anti-peeping driving voltage VH in the activation period of the anti-peeping driving circuit 51, so as to drive the anti-peeping light-emitting device 22 to emit light. The second reset voltage VREF1 is transmitted in an activation period of the second reset circuit 42, so as to reset the first electrode of the display light-emitting device 21 in the display pixel circuit 50.

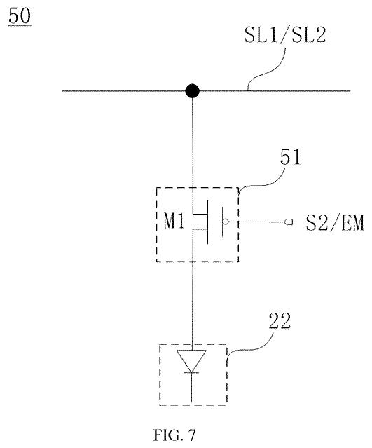

Exemplarily, as shown in FIG. 7, which is a schematic diagram of an anti-peeping pixel circuit according to an embodiment of the present disclosure, the anti-peeping driving circuit 51 includes an anti-peeping transistor M1. A first electrode of the anti-peeping transistor M1 is electrically connected to an input terminal of the anti-peeping driving circuit 51, and a second electrode of the anti-peeping transistor M1 is electrically connected to an output terminal of the anti-peeping driving circuit 51. That is, the first electrode of the anti-peeping transistor M1 may be electrically connected to the first reset voltage signal line SL1 or the second reset voltage signal line SL2, and the second electrode of the anti-peeping driving transistor M2 is electrically connected to the first electrode of the anti-peeping light-emitting device 22.

In this way, the anti-peeping pixel circuit 50 may include only one transistor, which is beneficial to simplifying the structure of the anti-peeping pixel circuit 50. In an embodiment of the present disclosure, the anti-peeping transistor M1 may be a single-gate transistor or a double-gate transistor. When the anti-peeping transistor M1 is the dual-gate transistor, two gates of the anti-peeping transistor M1 may be connected to the same scan signal line. In addition, the anti-peeping transistor MI may further include sub-transistors connected in series, so as to reduce the influence of the leakage current of the anti-peeping transistor M1 on the brightness of the anti-peeping light-emitting device 22.

As shown in FIG. 3 and FIG. 7, in an embodiment of the present disclosure, the display panel 01 includes scan signal lines. The scan signal lines include a first scan signal line S1, a second scan signal line S2, and a light-emitting control signal line EM.

A control terminal of the first reset circuit 41 and a control terminal of the second reset circuit 42 each are electrically connected to the first scan signal line S1. The display pixel circuit 40 further includes a data writing circuit 44 and a light-emitting control circuit 46. An input terminal of the data writing circuit 44 is electrically connected to the data signal line DL2, an output terminal of the data writing circuit 44 is electrically connected to the driving transistor Td, and a control terminal of the data writing circuit 44 is electrically connected to the second scan signal line S2. An input terminal of the light-emitting control circuit 46 is electrically connected to the driving transistor Td, an output terminal of the light-emitting control circuit 46 is electrically connected to the first electrode of the display light-emitting device 21, and a gate of the light-emitting control circuit 46 is electrically connected to the light-emitting control signal line EM.

The control terminal of the anti-peeping driving circuit 51 is electrically connected to the second scanning line S2 or the light-emitting control signal line EM.

In an embodiment of the present disclosure, the control terminal of the anti-peeping driving circuit 51 is electrically connected to the second scanning line S2 or the light-emitting control signal line EM. In the anti-peeping display mode, the anti-peeping driving circuit 51 may be activated simultaneously with the data writing circuit 44 or the light-emitting control circuit 46, while the activation period of the anti-peeping driving circuit 51 is different the activation period of the first reset circuit 41 and the activation period of the second reset circuit 42.

When the input terminal of the anti-peeping driving circuit 51 is electrically connected to the first reset voltage signal line SL1, the first reset voltage signal line SL1 may transmit the anti-peeping driving voltage VH and the first reset voltage VREF1 in a time-division manner, so as to meet the driving requirement of the anti-peeping light-emitting device 21 for emitting light and the requirement for resetting the gate of the driving transistor Td.

When the input terminal of the anti-peeping driving circuit 51 is electrically connected to the second reset voltage signal line SL2, the first reset voltage signal line SL1 may transmit the anti-peeping driving voltage VH and the second reset voltage VREF2 in a time-division manner, so as to meet the driving requirement of the anti-peeping light-emitting device 21 for emitting light and a requirement for resetting the first electrode of the display light-emitting device 21.

Moreover, based on this arrangement, the anti-peeping pixel circuit 50 and the display pixel circuit 40 may share the second scan signal line S2 or the light-emitting control signal line EM, thereby being beneficial to reducing the number of scan signal lines in the display panel 01 and further reducing the structural complexity of the peripheral circuit for driving the anti-peeping pixel circuit 50 and the display pixel circuit 40, thus further simplifying the structure of the display panel 01.

Exemplarily, as shown in FIG. 3 and FIG. 7, when the gate of the anti-peeping transistor M1 is electrically connected to the second scan line S2, the channel type of the anti-peeping transistor M1 may be the same as the channel type of the fourth transistor T4. When the gate of the anti-peeping transistor MI is electrically connected to the light-emitting control signal line EM, the channel type of the anti-peeping transistor M1 may be the same as the channel type of the sixth transistor T6.

Exemplarily, the anti-peeping transistor M1, the fourth transistor T4 and the sixth transistor T6 are all P-type transistors.

It should be noted that, when the structure of the display pixel circuit 50 is shown in FIG. 4, since the control terminal of the first reset circuit 41 is electrically connected to the first scan signal line S1, the control terminal of the second reset circuit 42 is electrically connected to the second scan signal line S2, and the control terminal of the first reset circuit 41 and the control terminal of the second reset circuit 42 are not connected to a same scan signal line.

Therefore, when the input terminal of the anti-peeping driving circuit 51 is electrically connected to the first reset voltage signal line SL1, the control terminal of the anti-peeping driving circuit 51 may be electrically connected to other scan signal line except the first scan signal line S1, as long as it is ensured that the activation period of the anti-peeping driving circuit 51 is at least partially different from the activation period of the first reset circuit 41.

When the input terminal of the anti-peeping driving circuit 51 is electrically connected to the second reset voltage signal line SL2, the control terminal of the anti-peeping driving circuit 51 may be electrically connected to other scan signal line except the second scan signal line S2, as long as it is ensured that the activation period of the anti-peeping driving circuit 51 is at least partially different from the activation period of the second reset circuit 42.

In an embodiment of the present disclosure, in the normal display mode, during an activation period of the anti-peeping driving circuit 51, the input terminal of the anti-peeping driving circuit 51 receives a reset voltage, and the reset voltage is configured to reset the first electrode of the anti-peeping light-emitting device 22.

Based on this arrangement, when the anti-peeping pixel circuit 50 and the display pixel 40 share the scan signal line, even if the anti-peeping driving circuit 51 is activated in the normal display mode, since the input terminal of the anti-peeping driving circuit 51 receives the reset voltage at this moment, the anti-peeping light-emitting device 22 does not emit light, thereby preventing the anti-peeping light-emitting device 21 from affecting the full-view display of the display light-emitting device 21 in the normal display mode.

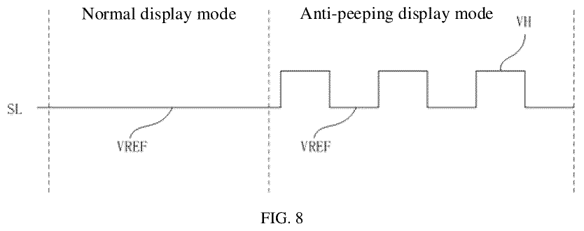

Exemplarily, as shown in FIG. 8, which is a schematic waveform diagram of a reset voltage signal line according to an embodiment of the present disclosure, the reset voltage signal line SL may be a first reset voltage signal line SL1 or a second reset voltage signal line SL2. In the normal display mode, the reset voltage signal line SL transmits a reset voltage VREF. The reset voltage VREF may be a first reset voltage VREF1 transmitted by the first reset voltage signal line SL1, or may be a second reset voltage VREF2 transmitted by the second reset voltage signal line SL2, so as to prevent the anti-peeping light-emitting device 22 from emitting light in the normal display mode.

In the anti-peeping display mode, the reset voltage signal line SL may transmit the reset voltage VREF and the anti-peeping driving voltage VH in a time-division manner, to meet the light-emitting requirement of the anti-peeping light-emitting device 22 and the normal operation of the display pixel circuit 40.

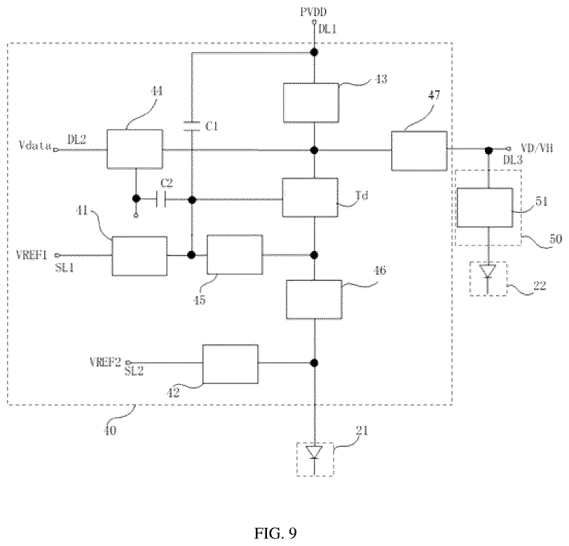

FIG. 9 is a schematic diagram of connection between another anti-peeping pixel circuit and a display pixel circuit according to an embodiment of the present disclosure.

In an embodiment of the present disclosure, as shown in FIG. 9, the display pixel circuit 40 further includes a bias adjustment circuit 47. An input terminal of the bias adjustment circuit 47 is electrically connected to a bias voltage signal line DL3, an output terminal of the bias adjustment circuit 47 is electrically connected to the driving transistor Td. The bias voltage signal line DL3 is configured to transmit a bias adjustment voltage VD to the bias adjustment circuit 47. The bias adjustment circuit 47 transmits the bias adjustment voltage VD to the driving transistor Td, so as to help a bias state of the driving transistor Td.

Exemplarily, as shown in FIG. 9, the bias adjustment circuit 47 and the data writing circuit 44 each are electrically connected to the first electrode of the driving transistor Td.

Exemplarily, as shown in FIG. 9, the display pixel circuit 40 further includes a second storage capacitor C2. An electrode plate of the second storage capacitor C2 is electrically connected to the gate of the driving transistor Td, and another electrode plate of the second storage capacitor C2 is electrically connected to the control terminal of the data writing circuit 44, so as to improve the accuracy of transmitting the data voltage Vdata to the gate of the driving transistor Td.

The anti-peeping pixel circuit 50 includes an anti-peeping driving circuit 51. An input terminal of the anti-peeping driving circuit 51 is electrically connected to the bias voltage signal line DL3, and an output terminal of the anti-peeping driving circuit 51 is electrically connected to the first electrode of the anti-peeping light-emitting device 22. The bias voltage signal line DL3 is further configured to transmit an anti-peeping driving voltage VH to the anti-peeping driving circuit 51, and in the anti-peeping display mode, the bias adjustment voltage VD is reused as the anti-peeping driving voltage VH.

That is, in the anti-peeping display mode, the bias adjustment voltage VD received by the display pixel circuit 40 may be configured to drive the anti-peeping light-emitting device 22 to emit light.

Based on this arrangement, in an embodiment of the present disclosure, the display pixel circuit 40 and the anti-peeping pixel circuit 50 may share the same bias voltage signal line DL3. In the anti-peeping display mode, the bias adjustment voltage VD transmitted by the bias voltage signal line DL3 is reused as the anti-peeping driving voltage VH, which not only can realize the bias adjustment of the driving transistor Td in the display pixel circuit 40, but also can drive the anti-peeping light-emitting device 22 to emit light.

Moreover, in the anti-peeping display mode, the voltage on the bias voltage signal line DL3 requires no voltage transitions, thereby being beneficial to reducing the power consumption of the display panel 01.

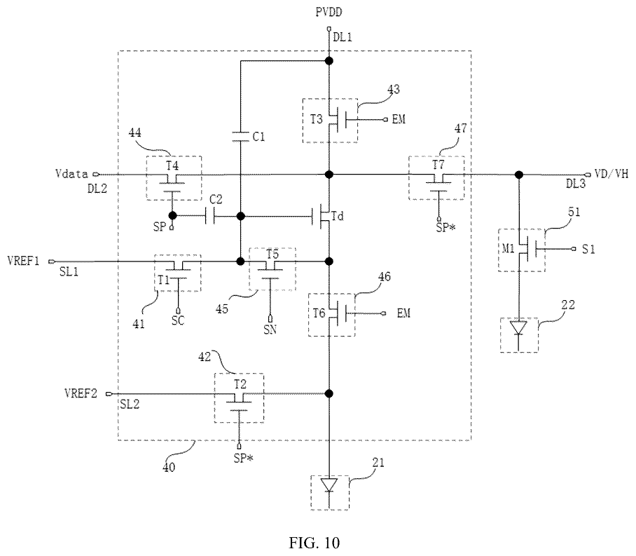

Exemplarily, as shown in FIG. 10, which is a schematic diagram of the anti-peeping pixel circuit and the display pixel circuit shown in FIG. 9, in the display pixel circuit 40, the bias adjustment circuit 47 includes a seventh transistor T7. A first electrode of the seventh transistor T7 is electrically connected to the bias voltage signal line DL3, a second electrode of the seventh transistor T7 is electrically connected to the first electrode of the driving transistor Td, and a gate of the seventh transistor T7 is electrically connected to a bias scan signal line SP*.

The first electrode of the first transistor T1 is electrically connected to the first reset voltage signal line SL1, the second electrode of the first transistor T1 is electrically connected to the gate of the driving transistor Td, and the gate of the first transistor T1 is electrically connected to a reset scan signal line SC. The first electrode of the second transistor T2 is electrically connected to the second reset voltage signal line SL2, the second electrode of the second transistor T2 is electrically connected to the first electrode of the display light-emitting device 21, and the gate of the second transistor T2 is electrically connected to the bias scan signal line SP*.

The first electrode of the third transistor T3 is electrically connected to the power supply voltage signal line DL1, the second electrode of the third transistor T3 is electrically connected to the first electrode of the driving transistor Td, and the gate of the third transistor T3 is electrically connected to the light-emitting control signal line EM. The first electrode of the fourth transistor T4 is electrically connected to the data signal line DL2, the second electrode of the fourth transistor T4 is electrically connected to the first electrode of the driving transistor Td, and the gate of the fourth transistor T4 is electrically connected to a data scan signal line SP.

The first electrode of the fifth transistor T5 is electrically connected to the second electrode of the driving transistor Td, the second electrode of the fifth transistor T5 is electrically connected to the gate of the driving transistor Td, and the gate of the fifth transistor T5 is electrically connected to a threshold scan signal line SN. The first electrode of the sixth transistor T6 is electrically connected to the second electrode of the driving transistor Td, the second electrode of the sixth transistor T6 is electrically connected to the first electrode of the display light-emitting device 21, and the gate of the sixth transistor T6 is electrically connected to the light-emitting control signal line EM.

In the anti-peeping pixel circuit 50, the anti-peeping driving circuit 51 includes an anti-peeping transistor M1. A first electrode of the anti-peeping transistor M1 is electrically connected to the bias voltage signal line DL3, a second electrode of the anti-peeping transistor M1 is electrically connected to the first electrode of the anti-peeping light-emitting device 22, and a gate of the anti-peeping transistor M1 is electrically connected to the first scan line S1.

Exemplarily, as shown in FIG. 10, the driving transistor Td, the first transistor T1, the second transistor T2, the third transistor T3, the fourth transistor T4, the fifth transistor T5, the sixth transistor T6, the seventh transistor T7 and the anti-peeping transistor M1 are all N-type transistors.

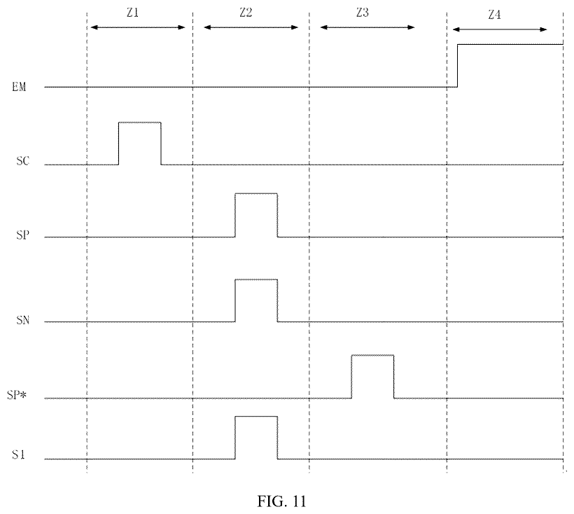

FIG. 11 is a timing diagram of the anti-peeping pixel circuit and the display pixel circuit shown in FIG. 10.

Exemplarily, as shown in FIG. 11, in one frame of display image, the operation process of the display pixel circuit 40 includes a reset phase Z1, a data writing phase Z2, a bias adjustment phase Z3 and a light-emitting phase Z4.

In the reset phase Z1, the first transistor T1 is activated, and the first reset voltage VREF1 is transmitted to the gate of the driving transistor Td through the first transistor T1, so as to complete the reset of the gate of the driving transistor Td.

In the data writing phase Z2, the fourth transistor T4 and the fifth transistor T5 are activated, and the data voltage Vdata is transmitted to the gate of the driving transistor Td through the fourth transistor T4, the driving transistor Td and the fifth transistor T5.

In the bias adjustment phase Z3, the seventh transistor T7 and the second transistor T2 are activated, and the bias adjustment voltage VD is transmitted to the first electrode of the driving transistor Td through the seventh transistor T7, so as to adjust the bias state of the driving transistor Td. The second reset voltage VREF2 is transmitted to the first electrode of the display light-emitting device 21 through the second transistor T2, so as to complete the reset of the first electrode of the display light-emitting device 21.

In the light-emitting phase Z4, the third transistor T3 and the sixth transistor T6 are activated, and light-emitting driving current generated by the driving transistor Td is transmitted to the display light-emitting device 21, so as to drive the display light-emitting device 21 to emit light.

In the anti-peeping display mode, the anti-peeping driving circuit 51 is activated in at least one of the reset phase Z1, the data writing phase Z2, the bias adjustment phase Z3 and the light-emitting phase Z4.

Exemplarily, as shown in FIG. 11, in the data writing phase Z2, the first scan line S1 transmits an enable signal to control the anti-peeping transistor MI to be activated. That is, in the anti-peeping display mode, the anti-peeping driving circuit 51 and the data writing circuit 44 may be activated simultaneously.

Based on this arrangement, within a time period of one frame of image in the anti-peeping display mode, a time period during which the anti-peeping light-emitting device 22 emits light is relatively flexible, which is beneficial to improving the flexibility of driving the anti-peeping light-emitting device 22 to emit light.

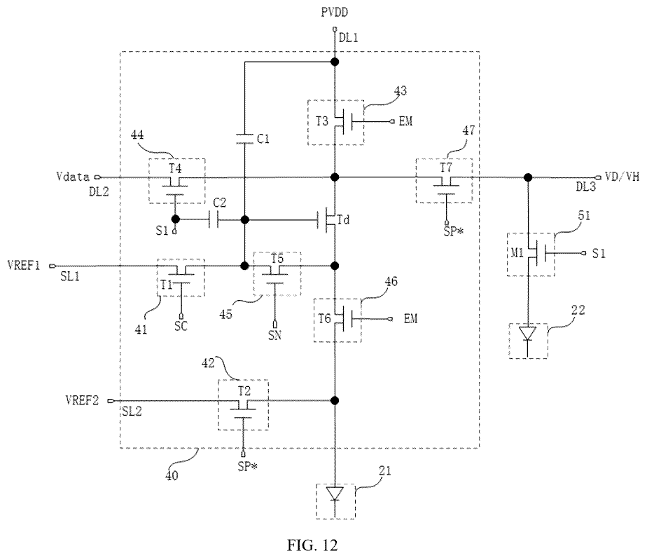

FIG. 12 is another schematic diagram of the anti-peeping pixel circuit and the display pixel circuit shown in FIG. 9. The only difference between the circuit shown in FIG. 12 differs from the circuit shown in FIG. 10 is that the gate of the fourth transistor T4 is electrically connected to the first scan line S1.

In an embodiment of the present disclosure, as shown in FIG. 12, the display panel 01 includes scan signal lines, and the scan signal lines include a first scan signal line S1.

The anti-peeping driving circuit 51 is electrically connected to the first scan signal line S1, and the display pixel circuit 40 is electrically connected to the first scan signal line S1.

That is, the anti-peeping pixel circuit 50 and the display pixel circuit 40 may not only share the same bias voltage signal line DL3, but also share the same first scan signal line S1. The anti-peeping driving circuit 51 and the data writing circuit 44 may be activated simultaneously.

In this way, it is beneficial to reducing the number of scan signal lines in the display panel 01 and further reducing the structural complexity of the peripheral circuit for driving the anti-peeping pixel circuit 50 and the display pixel circuit 40, thereby further simplifying the structure of the display panel 01.

It should be noted that the anti-peeping driving circuit 51 and any one of the first reset circuit 41, the second reset circuit 42, the power supply voltage writing circuit 43, the data writing circuit 44, the threshold compensation circuit 45 and the light-emitting control circuit 46 in the display pixel circuit 40 may share the scan signal line, and FIG. 12 merely illustrates a case in which the anti-peeping driving circuit 51 and the data writing circuit 44 share the scan signal line.

In an embodiment of the present disclosure, in the normal display mode, the bias voltage signal line DL3 transmits the bias adjustment voltage VD and the reset voltage in a time-division manner.

In an activation period of the anti-peeping driving circuit 51, the anti-peeping driving circuit 51 receives a reset voltage configured to reset the first electrode of the anti-peeping light-emitting device 22.

Based on this arrangement, when the anti-peeping pixel circuit 50 and the display pixel 40 share the scan signal line, even if the anti-peeping driving circuit 51 is activated in the normal display mode, since the anti-peeping driving circuit 51 receives the reset voltage at this moment, the anti-peeping light-emitting device 22 does not emit light, thereby preventing the anti-peeping light-emitting device 21 from affecting the full-view display of the display light-emitting device 21 in the normal display mode.

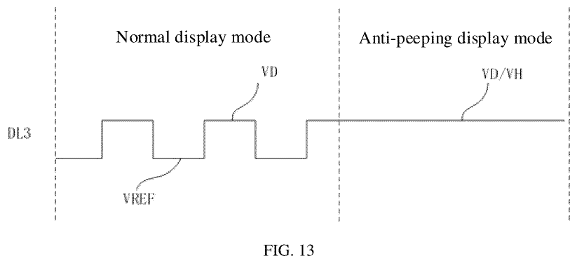

Exemplarily, as shown in FIG. 13, which is a schematic waveform diagram of a bias voltage signal line according to an embodiment of the present disclosure, in the anti-peeping display mode, the bias voltage signal line DL3 transmits the bias adjustment voltage VD. The bias adjustment voltage VD may not only satisfy the normal operation of the display pixel circuit 40, but also may be reused as the anti-peeping driving voltage VH, so as to drive the anti-peeping light-emitting device 22 to emit light.

In the normal display mode, the bias voltage signal line DL3 transmits the bias adjustment voltage VD and the reset voltage VREF in a time-division manner, which not only can satisfy the normal operation of the display pixel circuit 40, but also can prevent the anti-peeping light-emitting device 22 from emitting light.

In an embodiment of the present disclosure, the display panel 01 includes scan signal lines. A scan signal line electrically connected to the anti-peeping pixel circuit 40 is different from a scan signal line electrically connected to the display pixel circuit 40.

Exemplarily, as shown in FIG. 10, the anti-peeping pixel circuit 50 is only electrically connected to the first scan signal line S1, and the display pixel circuit 40 is not electrically connected to the first scan signal line S1.

That is, the anti-peeping pixel circuit 50 and the display pixel circuit 40 may only share the voltage signal line without sharing the scan signal line.

In this way, the operation process of the anti-peeping pixel circuit 50 and the operation process of the display pixel circuit 40 are independent from each other, thereby reducing the driving difficulty of the anti-peeping pixel circuit 50 and the display pixel circuit 40.

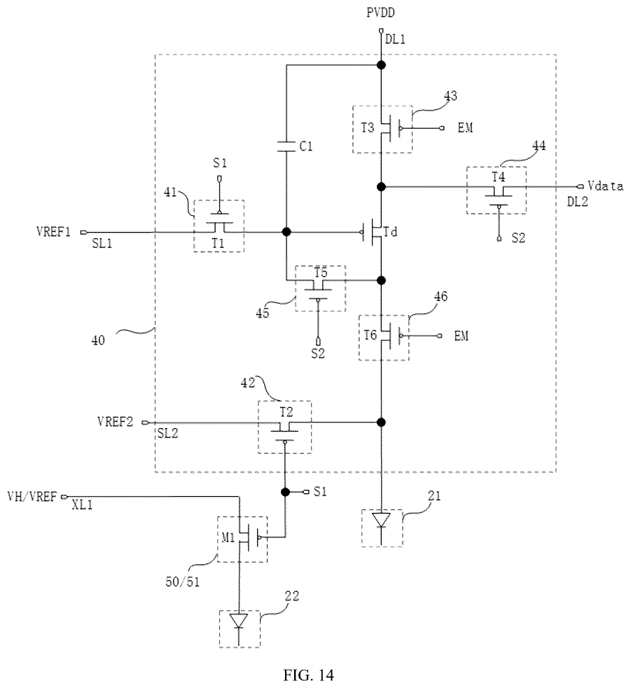

FIG. 14 is another schematic diagram of connection between an anti-peeping pixel circuit and a display pixel circuit according to an embodiment of the present disclosure.

As shown in FIG. 14, in an embodiment of the present disclosure, the display panel 01 includes scan signal lines. The scan signal lines include a first scan signal line S1 electrically connected to the display pixel circuit 40.

Exemplarily, as shown in FIG. 14, the first scan signal line S1 is electrically connected to the gates of the first transistor T1 and the second transistor T2 in the display pixel circuit 40.

The anti-peeping pixel circuit 50 includes an anti-peeping driving circuit 51. An input terminal of the anti-peeping driving circuit 51 is electrically connected to the first voltage signal line XL1, an output terminal of the anti-peeping driving circuit 51 is electrically connected to the first electrode of the anti-peeping light-emitting device 22, and a control terminal of the anti-peeping driving circuit 51 is electrically connected to the first scan signal line S1.

In the anti-peeping display mode, the first voltage signal line XL1 transmits the anti-peeping driving voltage VH to the anti-peeping driving circuit 51. In the normal display mode, the first voltage signal line XL1 transmits the reset voltage VREF to the anti-peeping driving circuit 51.

Exemplarily, as shown in FIG. 14, the anti-peeping driving circuit 51 includes an anti-peeping transistor M1. The first electrode of the anti-peeping transistor MI is electrically connected to the first voltage signal line XL1, the second electrode of the anti-peeping transistor M1 is electrically connected to the first electrode of the anti-peeping light-emitting device 22, and the gate of the anti-peeping transistor MI is electrically connected to the first scan signal line S1.

In the anti-peeping display mode, the anti-peeping transistor M1 transmits the anti-peeping driving voltage VH on the first voltage signal line XL1 to the anti-peeping light-emitting device 22, so as to drive the anti-peeping light-emitting device 22 to emit light. In the normal display mode, the anti-peeping transistor M1 transmits the reset voltage VREF on the first voltage signal line XL1 to the anti-peeping light-emitting device 22, so as to prevent the anti-peeping light-emitting device 22 from emitting light.

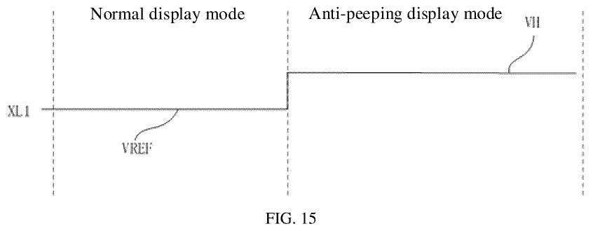

Exemplarily, as shown in FIG. 15, which is a schematic waveform diagram of a first voltage signal line according to an embodiment of the present disclosure, the first voltage signal line XL1 only transmits the anti-peeping driving voltage VH in the anti-peeping display mode, and the first voltage signal line XL1 only transmits the reset voltage VREF in the normal display mode.

The first voltage signal line XL1 is electrically insulated from the display pixel circuit 40.

That is, in an embodiment of the present disclosure, the anti-peeping pixel circuit 50 and the display pixel circuit 40 may only share the scan signal line without sharing the voltage signal line.

Based on this arrangement, while reducing the number of scan signal lines in the display panel 01, the first voltage signal line XL1 does not need to transmit jumping voltage signals in both the anti-peeping display mode and the normal display mode, thereby being beneficial to saving power consumption and reducing the driving difficulty of the display panel 01.

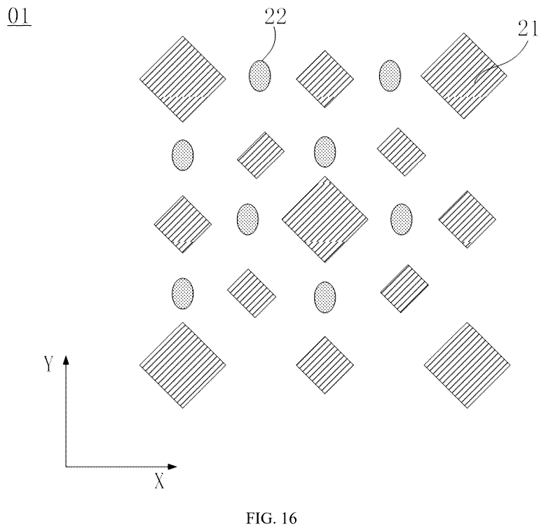

FIG. 16 is a partial plan diagram of a display panel according to an embodiment of the present disclosure.

In an embodiment of the present disclosure, as shown in FIG. 16, the anti-peeping light-emitting device 22 is located between two adjacent display light-emitting devices 21.

Exemplarily, as shown in FIG. 16, the display light-emitting devices 21 are arranged in an array in a first direction X and a second direction Y. The anti-peeping light-emitting device 22 may be located between two adjacent display light-emitting devices 21 in the first direction X, or may be located between two adjacent display light-emitting devices 21 in the second direction Y.

The first direction X may be a row direction in the display panel 01, and the second direction Y may be a column direction in the display panel 01.

In an embodiment of the present disclosure, the anti-peeping light-emitting device 22 is provided between two adjacent display light-emitting devices 21, so that the anti-peeping light-emitting device 22 may be closer to the display light-emitting device 21, thereby being beneficial to improving the interference effect of the anti-peeping light-emitting device 22 on the large viewing angle light emitted from the display light-emitting device 21, thus being beneficial to improving the anti-peeping effect of the display panel 01 in the anti-peeping display mode.

As a possible implementation, as shown in FIG. 1, a same light-emitting device 20 includes a first electrode 201, a first light-emitting layer 202 and a second electrode 203 that are stacked, and the second electrode 203 is located at a side of the first electrode 201 away from the substrate 10.

The first electrode 201 may be an anode of the light-emitting device 20, the second electrode 203 may be a cathode of the light-emitting device 20, and multiple light-emitting devices 20 may share a second electrode 203.

The first electrode 201 of the anti-peeping light-emitting device 22 is independent from the first electrode 201 of the display light-emitting device 21 adjacent thereto. The first light-emitting layer 202 of the anti-peeping light-emitting device 22 is integrally formed with the first light-emitting layer 202 of the display light-emitting device 21 adjacent thereto.

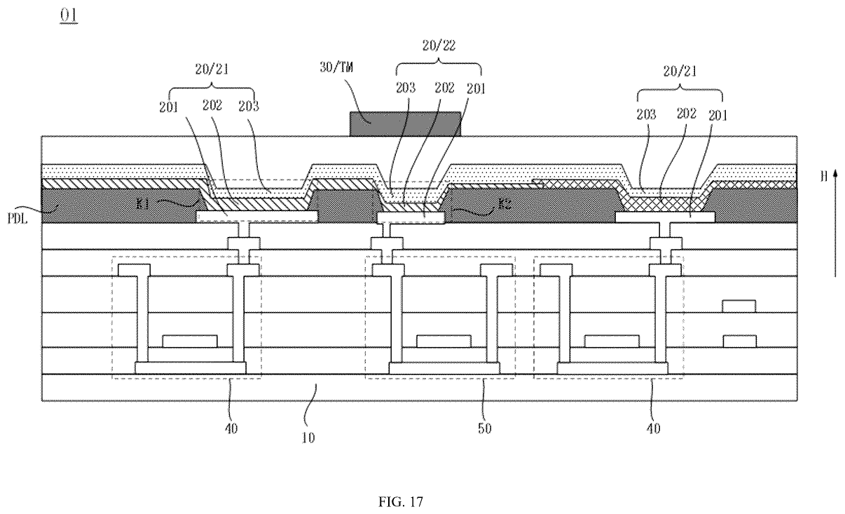

In an embodiment, as shown in FIG. 17, which is a schematic structural diagram of another display panel according to an embodiment of the present disclosure, a shaded portion of the first light-emitting layer 202 of the display light-emitting device 21 may be reused as the first light-emitting layer 202 of the anti-peeping light-emitting device 22.

When the light-emitting device 20 is an organic light-emitting diode (OLED), the display panel 01 is usually provided with a pixel definition layer PDL, and the pixel definition layer PDL is provided with a first opening K1 to define the position of the display light-emitting device 21. In the process of forming the first light-emitting layer 202 of the display light-emitting device 21, the material of the first light-emitting layer 202 may be evaporated into the first opening Kl of the pixel definition layer PDL by using a mask, thereby forming the first light-emitting layer of the display light-emitting device 21.

Since a hollow portion of the mask is usually larger than the first opening K1 of the pixel definition layer, when evaporating to form the first light-emitting layer 202 of the display light-emitting device 21, a part of the material of the first light-emitting layer 202 may deposit between the first openings K1 of two adjacent pixel definition layers PDL, and this part of the material of the first light-emitting layer 202 usually refers to a shaded portion of the first light-emitting layer 202 of the display light-emitting device 21. In an embodiment of the present disclosure, a second opening K2 may be provided in the pixel definition layer PDL, and the first electrode 201 of the anti-peeping light-emitting device 22 may be provided in the second opening K2. When forming the first light-emitting layer 202 of the display light-emitting device 21, the shaded portion of the first light-emitting layer 202 of the display light-emitting device 21 is formed in the second opening K2 as the first light-emitting layer 202 of the anti-peeping light-emitting device 22.

Based on this arrangement, the first electrodes 201 independent from each other may be driven separately to control the adjacent display light-emitting device 21 and anti-peeping light-emitting device 22 to emit light independently. Additionally, the shaded portion of the first light-emitting layer 202 of the display light-emitting device 21 may be configured as the first light-emitting layer of the anti-peeping light-emitting device 22, thereby being beneficial to avoiding the influence of the arrangement of the anti-peeping light-emitting device 22 on the pixel aperture ratio of the display panel 01, thus being beneficial to reducing the influence on the resolution of the display panel 01 while achieving the anti-peeping function of the display panel 01, and thus ensuring the display effect.

In an embodiment, as shown in FIG. 17, in the direction H perpendicular to the plane of the substrate 10, a projection area of the second opening K2 is smaller than a projection area of the first opening K1. In this way, the anti-peeping light-emitting device 22 may be provided relatively small, which is beneficial to reducing the area of the shielding layer 30 covering the anti-peeping light-emitting device 22, thereby ensuring a higher transmittance of the display panel 01.

In an embodiment, the anti-peeping light-emitting device 22 includes at least one of a red light-emitting device and a green light-emitting device. That is, the anti-peeping light-emitting device 22 may share a same first light-emitting layer with the red display light-emitting device, or may share a same first light-emitting layer with the green display light-emitting device.

Compared with a blue light-emitting device, a service life of the red light-emitting device and a service life of the green light-emitting device are generally longer, so that the anti-peeping light-emitting device 22 includes at least one of the red light-emitting device or the green light-emitting device, thereby being beneficial to improving the service life of the anti-peeping light-emitting device 22, thus being beneficial to enhancing the reliability of the anti-peeping display of the display panel 01.

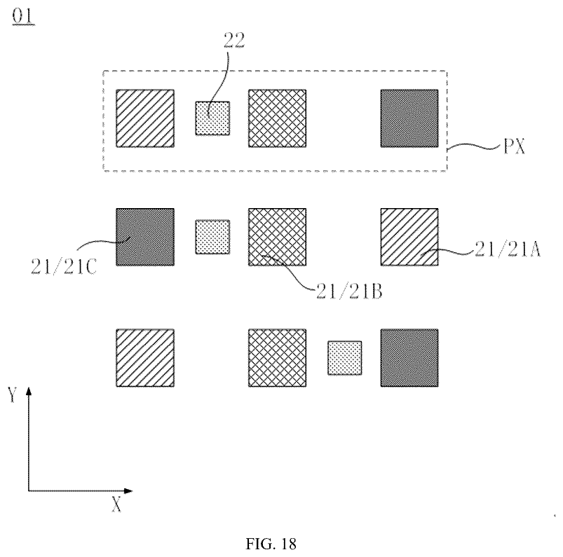

FIG. 18 is a partial plan diagram of another display panel according to an embodiment of the present disclosure.

As shown in FIG. 18, in an embodiment of the present disclosure, the display panel 01 includes pixel units PX including at least three adjacent display light-emitting devices 21 of different colors.

Exemplarily, as shown in FIG. 18, the display light-emitting devices 21 include a red display light-emitting device 21A, a green display light-emitting device 21B and a blue display light-emitting device 21C, and one of the pixel units PX includes a red display light-emitting device 21A, a green display light-emitting device 21B and a blue display light-emitting device 21C adjacent in the first direction X.

In a same pixel unit PX, an anti-peeping light-emitting device 22 is provided between at least two adjacent display light-emitting devices 21. That is, a same pixel unit PX further includes at least one anti-peeping light-emitting device 22.

In an embodiment of the present disclosure, a same pixel unit PX includes at least one anti-peeping light-emitting device 22. Then, in the anti-peeping display mode, when the pixel unit PX and the anti-peeping light-emitting device 22 included therein emit light, the large viewing angle light emitted by the anti-peeping light-emitting device 22 can effectively interfere with the large viewing angle display image of the pixel unit PX, which is beneficial to improving the anti-peeping effect of the display panel 01.

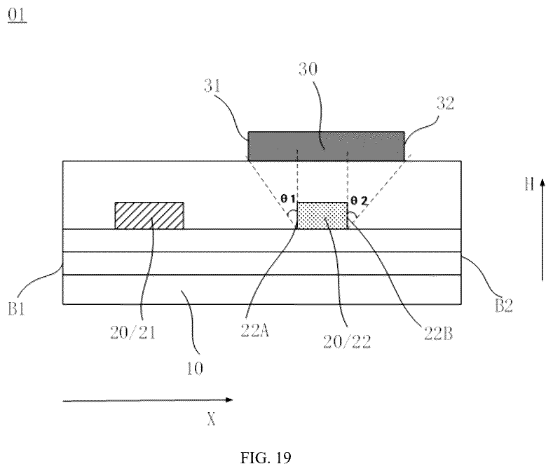

FIG. 19 is a schematic structural diagram of a further display panel according to an embodiment of the present disclosure.

In an embodiment of the present disclosure, as shown in FIG. 19, the display panel 01 includes a first edge B1 and a second edge B2 opposite to each other along the first direction X, the shielding layer 30 includes a first side surface 31 and a second side surface 32 opposite to each other along the first direction X, and the first side surface 31 is closer to the first edge B1 than the second side surface 32.

The anti-peeping light-emitting device 22 includes a third side surface 22A and a fourth side surface 22B opposite to each other along the first direction X, and the third side surface 22A is closer to the first edge B1 than the fourth side surface 22B.

In the first direction X, the first side surface 31 is closer to the first edge B1 than the third side surface 22A, and an included angle between a line connecting the third side surface 22A and the first side surface 31 and a normal line of the substrate 10 is θ1, where 0°<θ1≤60°.

In an embodiment of the present disclosure, at the first edge B1 of the display panel 01, light of a small viewing angle not greater than θ1 emitted by the anti-peeping light-emitting device 22 may be shielded by the shielding layer 30, while light of a large viewing angle greater than θ1 emitted by the anti-peeping light-emitting device 22 may be emitted, thereby affecting a display image of the display panel at a large viewing angle greater than θ1. In this way, anti-peeping the large viewing angle image of the display panel θ1 at the first edge B1 can be achieved without affecting the front display of the display panel.

For example, θ1=45°.

In an embodiment of the present disclosure, still referring to FIG. 19, in the first direction X, the second side surface 32 is closer to the second edge B2 than the fourth side surface 22B, and an included angle between a line connecting the fourth side surface 22B and the second side surface 32 and a normal line of the substrate 10 is θ2, where θ2=θ1.

In an embodiment of the present disclosure, at the second edge B2 of the display panel 01, light of a small viewing angle not greater than θ2 emitted by the anti-peeping light-emitting device 22 may be shielded by the shielding layer 30, while light of a large viewing angle greater than θ2 emitted by the anti-peeping light-emitting device 22 may be emitted, thereby affecting a display image of the display panel at a large viewing angle greater than θ2. In this way, anti-peeping the large viewing angle image of the display panel 01 at the second edge B2 can be achieved without affecting the front display of the display panel.

In addition, if θ2=θ1, anti-peeping levels of the display panel 01 at the first edge B1 side and at the second edge B2 side may tend to be consistent, which is beneficial to reducing the structural complexity of the display panel 01 while improving the anti-peeping range of the display panel 01.

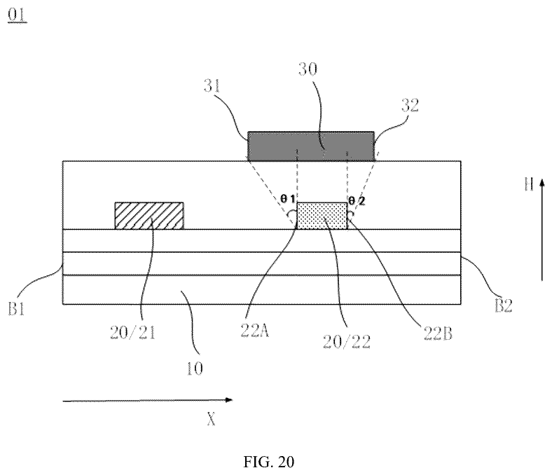

FIG. 20 is a schematic structural diagram of another display panel according to an embodiment of the present disclosure.

In an embodiment of the present disclosure, as shown in FIG. 20, in the first direction X, the second side surface 32 is closer to the second edge B2 than the fourth side surface 22B, and an included angle between a line connecting the fourth side surface 22B and the second side surface 32 and a normal line of the substrate 10 is θ2, where 0°<θ2≤60° and θ2≠θ1.

In an embodiment of the present disclosure, at the second edge B2 of the display panel 01, light of a small viewing angle not greater than θ2 emitted by the anti-peeping light-emitting device 22 may be shielded by the shielding layer 30, while light of a large viewing angle greater than θ2 emitted by the anti-peeping light-emitting device 22 may be emitted, thereby affecting a display image of the display panel at a large viewing angle greater than θ2. In this way, anti-peeping the large viewing angle image of the display panel 01 at the second edge B2 can be achieved without affecting the front display of the display panel.

Moreover, if θ2≠θ1, anti-peeping levels of the display panel 01 at the first edge B1 side and at the second edge B2 may be different from each other, which is beneficial to flexibly configuring anti-peeping effects at different edge sides according to actual anti-peeping requirements of the display panel 01 while improving the anti-peeping range of the display panel 01.

In an embodiment of the present disclosure, as shown in FIG. 1, the display panel 01 includes a touch wire TM. The touch wire TM is located at a side of the light-emitting device 20 away from the substrate 10, and the touch wire TM is reused as the shielding layer 30.

Based on this configuration, the display panel 01 provided by an embodiment of the present disclosure may further have a touch function. At the same time, if the touch wire TM is configured as the shielding layer 30, there is no need to provide the shielding layer 30 additionally in the display panel 01, which is beneficial to thinning of the display panel 01.

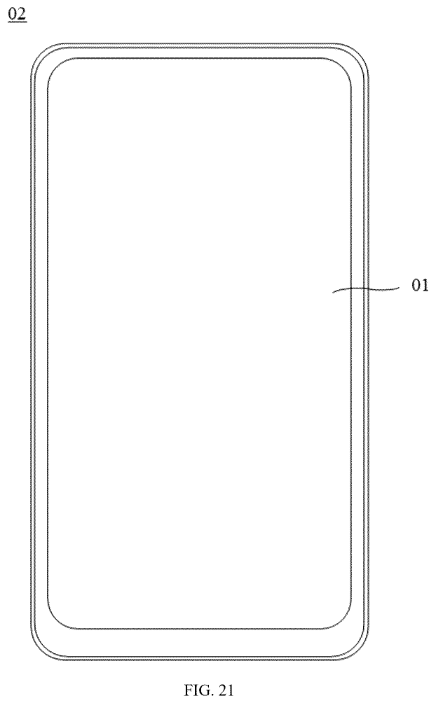

FIG. 21 is a schematic diagram showing a display apparatus according to an embodiment of the present disclosure.

An embodiment of the present disclosure provides a display device 02, as shown in FIG. 21, and the display device 02 includes the display panel 01 provided by the above-mentioned embodiments. For example, the display device 02 may be an electronic device such as a mobile phone, a notebook computer, a tablet computer, a vehicle-mounted display, or a wearable display, there is no limitation herein.

In the display device 02, in the normal display mode of the display panel 01, the display light-emitting device 21 is configured to emit light, while the anti-peeping light-emitting device 22 does not emit light, so that the light emitted from the display light-emitting device 21 is not interfered by the anti-peeping light-emitting device 22, thereby realizing normal display of the display light-emitting device 21. In the anti-peeping display mode of the display panel 01, both the display light-emitting device 21 and the anti-peeping light-emitting device 22 emit light, so that a small viewing angle light emitted by the anti-peeping light-emitting device 22 can be shielded by the shielding layer 30, and a large viewing angle light can interfere with a large viewing angle display of the display light-emitting device 21, thereby realizing large viewing angle anti-peeping without affecting the front display of the display panel 01, preventing the display content of the display panel 01 from being peeped by the surrounding people, and thus meeting users' demands for active anti-peeping of the display device 02.

Moreover, the arrangement of the anti-peeping pixel circuit 50 and the display pixel circuit 40 sharing a same voltage signal line and/or a same scan signal line is also beneficial to reducing the structural complexity of the peripheral circuit driving the anti-peeping pixel circuit 50 and the display pixel circuit 40, and thus simplifying the structure of the display panel 01.

The above description merely illustrates some preferred embodiments of the present disclosure and is not intended to limit the present disclosure, and any modification, equivalent substitution, improvement and the like made within a spirit and a principle of the present disclosure shall fall with a scope of the present disclosure.

What is claimed is:

1. A display panel, comprising:
a substrate;
light-emitting devices located at a side of the substrate and comprising a display light-emitting device and an anti-peeping light-emitting device;
a shielding layer located at a side of the anti-peeping light-emitting device away from the substrate, wherein along a direction perpendicular to a plane of the substrate, the shielding layer completely covers the anti-peeping light-emitting device and does not overlap with the display light-emitting device; and
a display pixel circuit and an anti-peeping pixel circuit that are located between the substrate and the light-emitting devices, wherein the display pixel circuit is electrically connected to the display light-emitting device, and the anti-peeping pixel circuit is electrically connected to the anti-peeping light-emitting device,
wherein,
display modes of the display panel comprise a normal display mode and an anti-peeping display mode; in the normal display mode, the display light-emitting device emits light and the anti-peeping light-emitting device does not emit light; and in the anti-peeping display mode, both the display light-emitting device and the anti-peeping light-emitting device emit light; and
both the anti-peeping pixel circuit and the display pixel circuit are electrically connected to a same voltage signal line, and/or both the anti-peeping pixel circuit and the display pixel circuit are electrically connected to a same scan signal line.

2. The display panel according to claim 1, wherein,
the display pixel circuit comprises a driving transistor, a first reset circuit and a second reset circuit, an input terminal of the first reset circuit is electrically connected to a first reset voltage signal line, an output terminal of the first reset circuit is electrically connected to a gate of the driving transistor, and the first reset voltage signal line is configured to transmit a first reset voltage to the first reset circuit; and
an input terminal of the second reset circuit is electrically connected to a second reset voltage signal line, an output terminal of the second reset circuit is electrically connected to a first electrode of the display light-emitting device, and the second reset voltage signal line is configured to transmit a second reset voltage to the second reset circuit.

3. The display panel according to claim 2, wherein,
the anti-peeping pixel circuit comprises an anti-peeping driving circuit, an input terminal of the anti-peeping driving circuit is electrically connected to the first reset voltage signal line, an output terminal of the anti-peeping driving circuit is electrically connected to a first electrode of the anti-peeping light-emitting device, and the first reset voltage signal line is configured to transmit an anti-peeping driving voltage to the anti-peeping driving circuit; and in the anti-peeping display mode, an activation period of the first reset circuit is at least partially different from an activation period of the anti-peeping driving circuit, and the first reset voltage signal line transmits the first reset voltage and the anti-peeping driving voltage in a time-division manner.

4. The display panel according to claim 2, wherein,
the anti-peeping pixel circuit comprises an anti-peeping driving circuit; an input terminal of the anti-peeping driving circuit is electrically connected to the second reset voltage signal line, an output terminal of the anti-peeping driving circuit is electrically connected to a first electrode of the anti-peeping light-emitting device, and the second reset voltage signal line is configured to transmit an anti-peeping driving voltage to the anti-peeping driving circuit; and in the anti-peeping display mode, an activation period of the second reset circuit is at least partially different from an activation period of the anti-peeping driving circuit, and the second reset voltage signal line transmits the second reset voltage and the anti-peeping driving voltage in a time-division manner.

5. The display panel according to claim 3, wherein,
the display panel comprises scan signal lines comprising a first scan signal line, a second scan signal line and a light-emitting control signal line;
a control terminal of the first reset circuit and a control terminal of the second reset circuit each are electrically connected to the first scan signal line; the display pixel circuit further comprises a data writing circuit and a light-emitting control circuit; an input terminal of the data writing circuit is electrically connected to a data signal line, an output terminal of the data writing circuit is electrically connected to the driving transistor, and a control terminal of the data writing circuit is electrically connected to the second scan signal line; and an input terminal of the light-emitting control circuit is electrically connected to the driving transistor, an output terminal of the light-emitting control circuit is electrically connected to the first electrode of the display light-emitting device, and a gate of the light-emitting control circuit is electrically connected to the light-emitting control signal line;
a control terminal of the anti-peeping driving circuit is electrically connected to the second scan signal line or the light-emitting control signal line; and
in the normal display mode, an input terminal of the anti-peeping driving circuit receives a reset voltage during the activation period of the anti-peeping driving circuit.

6. The display panel according to claim 4, wherein,
the display panel comprises scan signal lines comprising a first scan signal line, a second scan signal line and a light-emitting control signal line;
a control terminal of the first reset circuit and a control terminal of the second reset circuit each are electrically connected to the first scan signal line; the display pixel circuit further comprises a data writing circuit and a light-emitting control circuit; an input terminal of the data writing circuit is electrically connected to a data signal line, an output terminal of the data writing circuit is electrically connected to the driving transistor, and a control terminal of the data writing circuit is electrically connected to the second scan signal line; and an input terminal of the light-emitting control circuit is electrically connected to the driving transistor, an output terminal of the light-emitting control circuit is electrically connected to the first electrode of the display light-emitting device, and a gate of the light-emitting control circuit is electrically connected to the light-emitting control signal line;
a control terminal of the anti-peeping driving circuit is electrically connected to the second scan signal line or the light-emitting control signal line; and
in the normal display mode, an input terminal of the anti-peeping driving circuit receives a reset voltage during the activation period of the anti-peeping driving circuit.

7. The display panel according to claim 2, wherein,
the display pixel circuit further comprises a bias adjustment circuit; an input terminal of the bias adjustment circuit is electrically connected to a bias voltage signal line, an output terminal of the bias adjustment circuit is electrically connected to the driving transistor, and the bias voltage signal line is configured to transmit a bias adjustment voltage to the bias adjustment circuit; and
the anti-peeping pixel circuit comprises an anti-peeping driving circuit; an input terminal of the anti-peeping driving circuit is electrically connected to the bias voltage signal line, an output terminal of the anti-peeping driving circuit is electrically connected to a first electrode of the anti-peeping light-emitting device, and the bias voltage signal line is configured to transmit an anti-peeping driving voltage to the anti-peeping driving circuit; and
in the anti-peeping display mode, the bias adjustment voltage is reused as the anti-peeping driving voltage.

8. The display panel according to claim 7, wherein,
an operation process of the display pixel circuit comprises a reset phase, a data writing phase, a bias adjustment phase and a light-emitting phase;
in the anti-peeping display mode, the anti-peeping driving circuit is activated in at least one of the reset phase, the data writing phase, the bias adjustment phase or the light-emitting phase;
the display panel comprises scan signal lines comprising a first scan signal line; and
the anti-peeping driving circuit is electrically connected to the first scan signal line, and the display pixel circuit is electrically connected to the first scan signal line.

9. The display panel according to claim 8, wherein,
in the normal display mode, the bias voltage signal line transmits the bias adjustment voltage and a reset voltage in a time-division manner; and
the anti-peeping driving circuit receives the reset voltage during an activation period of the anti-peeping driving circuit.

10. The display panel according to claim 1, wherein,
the display panel comprises scan signal lines; and
the scan signal line electrically connected to the anti-peeping pixel circuit is different from the scan signal line electrically connected to the display pixel circuit.

11. The display panel according to claim 1, wherein,
the display panel comprises scan signal lines comprising a first scan signal line, and the first scan signal line is electrically connected to the display pixel circuit;
the anti-peeping pixel circuit comprises an anti-peeping driving circuit; an input terminal of the anti-peeping driving circuit is electrically connected to a first voltage signal line, an output terminal of the anti-peeping driving circuit is electrically connected to a first electrode of the anti-peeping light-emitting device, and a control terminal of the anti-peeping driving circuit is electrically connected to the first scan signal line;
in the anti-peeping display mode, the first voltage signal line transmits an anti-peeping driving voltage to the anti-peeping driving circuit; and in the normal display mode, the first voltage signal line transmits a reset voltage to the anti-peeping driving circuit; and
the first voltage signal line is electrically insulated from the display pixel circuit.

12. The display panel according to claim 1, wherein,
the anti-peeping light-emitting device is located between two adjacent display light-emitting devices.

13. The display panel according to claim 12, wherein,
one light-emitting device of the light-emitting devices comprises a first electrode, a first light-emitting layer, and a second electrode that are stacked; and the second electrode is located at a side of the first electrode away from the substrate; and
the first electrode of the anti-peeping light-emitting device is independent from the first electrode of the display light-emitting device adjacent thereto; and the first light-emitting layer of the anti-peeping light-emitting device is integrally formed with the first light-emitting layer of the display light-emitting device adjacent thereto; and the anti-peeping light-emitting device comprises at least one of a red light-emitting device or a green light-emitting device.

14. The display panel according to claim 12, wherein,
the display panel comprises pixel units, one of which comprises at least three adjacent display light-emitting devices of different colors; and
the anti-peeping light-emitting device is provided between at least two adjacent display light-emitting devices in a same pixel unit.

15. The display panel according to claim 1, wherein,
the display panel comprises a first edge and a second edge opposite to each other along a first direction, the shielding layer comprises a first side surface and a second side surface opposite to each other along the first direction, and the first side surface is closer to the first edge than the second side surface;
the anti-peeping light-emitting device comprises a third side surface and a fourth side surface opposite to each other along the first direction, and the third side surface is closer to the first edge than the fourth side surface; and
the first side surface is closer to the first edge than the third side surface in the first direction, and an included angle between a line connecting the third side surface and the first side surface and a normal line of the substrate is θ1, where 0°<θ1≤60°.

16. The display panel according to claim 15, wherein,
in the first direction, the second side surface is closer to the second edge than the fourth side surface, and an included angle between a line connecting the fourth side surface and the second side surface and the normal line of the substrate is θ2, where θ2=θ1.

17. The display panel according to claim 15, wherein,
in the first direction, the second side surface is closer to the second edge than the fourth side surface, and an included angle between a line connecting the fourth side surface and the second side surface and the normal line of the substrate is θ2, where 0°<θ2≤60° and θ2≠θ1.

18. The display panel according to claim 1, wherein,
the display panel comprises a touch wire, the touch wire is located at a side of the light-emitting devices away from the substrate, and the touch wire is reused as the shielding layer.

19. A display device, comprising a display panel, comprising:
a substrate;
light-emitting devices located at a side of the substrate and comprising a display light-emitting device and an anti-peeping light-emitting device;
a shielding layer located at a side of the anti-peeping light-emitting device away from the substrate, wherein along a direction perpendicular to a plane of the substrate, the shielding layer completely covers the anti-peeping light-emitting device and does not overlap with the display light-emitting device; and
a display pixel circuit and an anti-peeping pixel circuit that are located between the substrate and the light-emitting devices, wherein the display pixel circuit is electrically connected to the display light-emitting device, and the anti-peeping pixel circuit is electrically connected to the anti-peeping light-emitting device,
wherein,
display modes of the display panel comprise a normal display mode and an anti-peeping display mode; in the normal display mode, the display light-emitting device emits light and the anti-peeping light-emitting device does not emit light; and in the anti-peeping display mode, both the display light-emitting device and the anti-peeping light-emitting device emit light; and
both the anti-peeping pixel circuit and the display pixel circuit are electrically connected to a same voltage signal line, and/or both the anti-peeping pixel circuit and the display pixel circuit are electrically connected to a same scan signal line.
